(19) United States
(12) Patent Application Publication
(10) Pub. No.: US 2023/0043085 A1
(43) Pub. Date: Feb. 9, 2023

(54) Component Carrier With Different Stack Heights and Vertical Opening and Manufacturing Methods

(71) Applicant: AT&S (China) Co Ltd, Shanghai (CN)

(72) Inventors: Seok Kim TAY, Singapore (SG); Mikael Andreas TUOMINEN, Pernio (FI)

(21) Appl. No.: 17/817,734

(22) Filed: Aug. 5, 2022

(30) Foreign Application Priority Data
Aug. 6, 2021 (CN) 202110902315.5

(51) Int. Cl. H05K 1/11; H01L 23/13; H01L 23/498; H01L 21/48; H05K 3/00; H05K 3/46

(52) U.S. Cl. CPC H05K 1/119; H01L 23/13; H01L 23/49822; H01L 21/4857; H05K 3/0029; H05K 3/0032; H05K 3/0047; H05K 3/4697; H05K 1/0274

(57) ABSTRACT

A component carrier includes a stack with at least one electrically conductive layer structure and at least one electrically insulating layer structure. The stack has at least one central stack section, at least one cavity stack section, and at least one vertical opening formed in the cavity stack section. The cavity stack section at least partially surrounds the central stack section, and the thickness of the central stack section is greater than the thickness of the cavity stack section.

### CROSS-REFERENCE TO RELATED APPLICATIONS

This application claims the benefit of the filing date of Chinese Patent Application No. 202110902315.5, filed Aug. 6, 2021, the disclosure of which is hereby incorporated herein by reference.

### TECHNICAL FIELD

Embodiments of the present invention relate to a component carrier, a method of manufacturing a component carrier, and a method of using a component carrier.

### BACKGROUND ART

In the context of growing product functionalities of component carriers equipped with one or more electronic components and increasing miniaturization of such components as well as a rising number of components to be mounted on the component carriers such as printed circuit boards, increasingly more powerful array like components or packages having several components are being employed, which have a plurality of contacts or connections, with ever smaller spacing between these contacts.

In particular optical components, for example camera modules, may become more and more important in the field of component carrier technology.

Conventionally, optical components are placed on the surface of component carriers such as printed circuit boards (PCB), for example using a socket connection during a final assembly step of the PCB. Hence, the optical components are arranged on a top surface of the PCB and thus protrude from the surface of the PCB. However, conventional optical components may suffer from a limited reliability and from damage due to the exposed arrangement.

### SUMMARY

Efficiently and safely assembling a (optical) component to a component carrier may be an issue.

There may be a need to assemble a (optical) component to a component carrier in an efficient and robust manner.

This need may be met by the subject matter according to the independent claims. Advantageous embodiments of the present invention are described by the dependent claims.

According to a first aspect of the invention, there is provided a component carrier comprising a stack with at least one electrically conductive layer structure and at least one electrically insulating layer structure. The stack comprises: i) at least one central stack section and ii) at least one cavity stack section. The cavity stack section (at least partially) surrounds the central stack section, wherein the thickness (in the vertical direction along the z-axis) of the central stack section is larger than the thickness of the cavity stack section. The component carrier further comprises at least one vertical opening formed in the cavity stack section.

According to a further aspect of the invention, there is provided an arrangement comprising a component carrier as described above, and an electronic element, wherein at least a part of the electronic element extends through at least part of the vertical opening of the component carrier.

According to another aspect of the invention, there is further provided a method of manufacturing a component carrier (for example a component carrier as described above). The method comprises i) providing a stack with at least one electrically conductive layer structure and at least one electrically insulating layer structure, wherein providing the stack comprises a) forming at least one central stack section in the stack and b) forming at least one cavity stack section in the stack, wherein the cavity stack section at least partially surrounds the central stack section. The thickness of the central stack section is larger than the thickness of the cavity stack section. The method further comprises ii) forming at least one vertical opening in the cavity stack section.

According to yet another aspect of the invention, there is described the use (method of using) of a component carrier as described above, to accommodate in the vertical opening of the component carrier at least a part of an electronic element which is not integrally formed with the component carrier.

### Overview of Embodiments

In the context of the present document, the term “component carrier” may particularly denote any support structure which is capable of accommodating one or more components thereon and/or therein for providing mechanical support and/or electrical connectivity. In other words, a component carrier may be configured as a mechanical and/or electronic carrier for (electronic) components. In particular, a component carrier may be one of a printed circuit board, an organic interposer, a (metal) core substrate, an inorganic substrate, and an IC (integrated circuit) substrate. A component carrier may also be a hybrid board combining different ones of the above-mentioned types of component carriers. The component carrier may be a multilayer component carrier, wherein at least two layers form a stack.

In the context of the present document, a component carrier may comprise “component carrier material”, or in other words, a connected arrangement of one or more electrically insulating layer structures and/or one or more electrically conductive layer structures as used in component carrier technology. More specifically, such component carrier material may be material as used for printed circuit boards (PCBs) or IC substrates. In particular, electrically conductive material of such a component carrier material may comprise copper. Electrically insulating material of the component carrier material may comprise resin, in particular epoxy resin, optionally in combination with reinforcing particles such as glass fibers and/or glass spheres.

In the context of the present document, the term “central stack section” may particularly denote a protruding section of the stack with respect to another section of the component carrier, e.g., a cavity stack section.

In the context of the present document, the term “cavity stack section” may particularly denote a recess (with respect to another section of the component carrier such as a central stack section), extending partially or entirely through and/or along a base structure. The cavity stack section may be configured for accommodating a component. A central stack section may be defined by the presence of cavity stack sections, i.e., recess sections that at least partially surround a protruding section. Hence, in an embodiment, the central stack section and the cavity stack section are formed in one and the same process step.

In the context of the present document, the term “thickness” may particularly denote an extension of the stack in a vertical direction (along the z-axis) of the stack. In other words, the stack may have a horizontal extension (e.g., corresponding to a plane of a respective layer) defined by a length and a width, and a vertical extension (or “height”), defined by a stacking direction of the layers of the stack, and perpendicular to the horizontal extension. The length (along the x-axis) and the width (along the y-axis) of a component carrier may be considered as the directions of main extension. The thickness along the z-axis may be considered as being perpendicular to the directions of main extension.

In the context of the present document, the term “vertical opening” may particularly denote an opening (or void or cut-out region) extending vertically (parallel to a stacking direction) (substantially) through at least some (in particular all) layers of a stack. In particular, the term “vertical opening” may denote an opening (or through hole), which is larger (in terms of diameter) than a conventional via or through hole as known in the art. However, the vertical opening hole may in some cases also be a blind hole, which only extends vertically through a part of the layers of a stack. The vertical opening may, in a preferred embodiment, have a substantially circular (horizontal) cross-section, but may also have, in other embodiments, other cross-sections such as a rectangular or a polygonal cross-section. The vertical opening may be configured for accommodating a component, such as an electronic element.

In the context of the present document, the term “electronic element” may particularly denote any electronic component suitable for being embedded in or on a component carrier. In particular, an electronic element may be an optical electronic component such as a camera or part of a camera, a light emitting element such as a light emitting diode (LED), and/or any sensor known in the art, such as a light sensor.

According to an exemplary embodiment, the invention may be based on the idea that an (optical) element can be assembled to a component carrier in an efficient, robust and flexible manner (in particular with respect to design options), when the component carrier layer stack is provided with different stack heights (in particular a central stack section height and a cavity stack section height), whereby a vertical (void) opening (“cut-out section”) is formed in the stack section with the lower height (being the cavity stack section).

Conventionally, (optical) components are surface mounted to a component carrier, whereby the risk of damage and malfunction may be highly increased.

It has now been found by the inventors that a surprisingly efficient assembly of an optical element to a component carrier may be achieved, when, as described above, a vertical opening is provided in a stack section with a low height. Such a design can for example be efficiently manufactured using a cut-out technique (e.g., based on a release layer and laser drilling). For example, by cutting out a section of the layer stack, a central stack section may remain as a protrusion that is surrounded by cavity stack sections that then represent recesses. Advantageously, the vertical opening may be formed before forming the cavity stack sections.

When assembling an electronic element (in particular providing an optical functionality) to the component carrier, the element may at least partially be accommodated in the vertical opening of the cavity stack section of the component carrier layer stack. Thereby, the electronic element is protected by the layer stack but still physically separate from the component carrier.

In the following, exemplary embodiments of the component carrier will be described.

According to an embodiment, the central stack section is arranged between two cavity stack sections. This may promote a compact design of the component carrier.

According to a further embodiment, the at least one vertical opening is at least partially void, in particular fully void. The vertical opening may for example be (partially) filled with electrically conductive material so as to form a via such as a (plated) through hole. Thus, a precise and reliable electric interconnection between two electrically conductive layer structures arranged on opposing sides of an electrically insulating layer structure may be established. If the vertical opening is only partially filled, such an electric interconnection may be established, while at the same time a void volume, e.g., for accommodating a component or an electronic element, is provided. A (partially) filled vertical opening may also prevent delamination of the stack and thus improve the mechanical stability of the component carrier.

According to a further embodiment, the component carrier further comprises a functional (or protective) coating layer covering at least one vertical side wall delimiting the vertical opening. This may provide the advantage that the vertical opening may be used for different applications in a design flexible manner.

According to a further embodiment, the functional coating layer comprises a black coating, in particular a black solder mask ink.

According to a further embodiment, the functional coating layer has a thickness of 25 μm (micrometers) or less.

According to a further embodiment, the functional coating layer is configured to prevent light scattering or to enhance light scattering.

According to yet another embodiment, the functional coating layer is optically opaque or transparent.

The functional coating layer may be electrically insulating or electrically conductive and/or is magnetic or non-magnetic (in particular magnetically insulating).

According to a further embodiment, the functional coating layer is anticorrosive, in particular waterproof and dustproof and/or water resistant and dust resistant.

Providing a functional coating layer on at least one vertical side wall delimiting the vertical opening may have the advantage that a roughness or unevenness of the sidewalls (e.g., stemming from a manufacturing process) may be compensated for. This may for example prevent light scattering and/or light refraction. Likewise, a black (solder mask ink) may also prevent light scattering and/or refraction. This may be important if, for example, an electronic element or a mechanical element (e.g., an optical element) is accommodated within the vertical opening. However, if preferred, a light intensity may be amplified by using a suitable functional coating layer. A functional coating layer may also prevent delamination of the stack and thus improve the mechanical stability of the component carrier. (Electro)magnetic shielding may also be provided by a functional coating layer according to embodiments of the invention. For example, magnetic particles may be comprised in the functional coating layer material. A small thickness of 25 μm or less of the functional coating layer may have the advantage that a coating layer may be provided and at the same time an electronic element may be accommodated in the vertical opening without the need to change the size (i.e., diameter) of the vertical opening or of the electronic element accommodated therein. An optically transparent functional coating layer may be useful for signal transmission. The functional coating layer may also prevent corrosion, which may for example occur due to heat generated by an electronic element accommodated within the vertical opening.

Hence, a functional coating layer according to embodiments of the invention may have various protective and/or optically advantageous effects.

According to a further embodiment, the at least one electrically conductive layer structure comprises a plurality of vertical through connections (such as copper filled vias) extending through the central stack section.

In another embodiment, the at least one electrically conductive layer structure comprises a plurality of vertical through connections extending through the cavity stack section. Vertical through connections may be used for electrically contacting an embedded electronic component (for instance pads of a semiconductor chip or pads of a passive component such as a capacitor) or (patterned) different electrically conductive layer structures, which are for example separated (insulated) by electrically insulating layer structures.

According to a further embodiment of the invention, the cavity stack section is free of vertical through connections. Hence, a component embedded in or on the cavity stack section may be efficiently electrically insulated. Furthermore, since the vertical opening is formed in the cavity stack section, manufacturing of an according component carrier may be carried out more efficiently, because the vertical opening can be formed anywhere in the cavity stack section regardless of vertical through connections. Thus, a cost-efficient component carrier may be provided. Furthermore, also an electronic element accommodated within the vertical opening may be more efficiently insulated or shielded from electric and/or magnetic interference of the vertical through connections.

According to a further embodiment, an angle between one vertical side wall delimiting the vertical opening and a first main surface of the cavity stack section is in the range between 80° and 100°, in particular (essentially) 90°. Thus, there may be provided undamaged, clean, sharp, and even edges, surfaces, and corners (i.e., at the points where a vertical side wall and a main surface of the cavity stack section converge). This may be particularly advantageous for preventing light scattering and/or refraction, which could otherwise occur due to rough and damaged edges, surfaces, and corners. Furthermore, damage of a component embedded on the carrier and/or accommodated in the vertical opening may be prevented.

According to an embodiment of the arrangement, the electronic element is not integrally formed with the component carrier. In particular, the electronic element is physically separate from the component carrier. For example, the electronic element may be embedded in or on a further component carrier. Advantageously, the component carrier comprising the vertical opening, and the electronic element may be manufactured in separate manufacturing steps and units and may be arranged together (or joined or assembled) at a later manufacturing step. Thus, damage to the electronic element, which may be very susceptible to mechanic and/or chemical and/or physical impacts, may be efficiently prevented during manufacture and during use. Furthermore, the arrangement promotes a compact design (i.e., a thinner design of the component carrier and thus a thinner design of any device comprising the component carrier and the electronic element), making it suitable for various applications.

According to a further embodiment of the arrangement, the electronic element is an optical element, in particular one of the group which consists of a camera, an LED, and a sensor, in particular a light sensor. Thus, the arrangement may be used in optical applications such as a (cell phone) camera, an optical sensor unit, a light detector.

According to an embodiment of the method, the method comprises forming the vertical opening by at least one of the group consisting of laser drilling and mechanical drilling. This allows for forming the vertical opening with high precision and high efficiency using established methodologies.

According to a further embodiment, providing the stack further comprises i) embedding a release layer in the stack, and ii) defining, by cutting and/or by drilling, in particular laser drilling, a cut-out portion in the stack. Drilling is preferably performed down to the embedded release layer to provide the cut-out portion directly on the release layer.

According to an embodiment, the method further comprises iii) removing the cut-out portion from the stack to provide the cavity stack section at least partially surrounding the central stack section. During manufacture, the cut-out portions may protect underlying layers from damage. Furthermore, mechanical stability of the component carrier is promoted during manufacture and thereafter. Embedding a release layer may have the advantage that the cut-out portion may be removed efficiently and without residues and/or damage to underlying layers, in particular electrically conductive layers.

According to a further embodiment, the method comprises forming the cavity stack section of the stack by means of routing. Thus, the cavity stack section may be formed precisely and efficiently.

According to a further embodiment of the method, forming the vertical opening is carried out before forming the cavity stack section of the stack. This is particularly advantageous for achieving an angle between one vertical side wall delimiting the vertical opening and a first main surface of the cavity stack section in the range between 80° and 100°, in particular 90°. In other words, forming the vertical opening before removing the cut-out portions may ensure that undamaged, clean, sharp, and even edges, surfaces, and corners may be achieved. This may be particularly advantageous for preventing light scattering and/or refraction, which could otherwise occur due to rough and damaged edges, surfaces, and corners. Furthermore, damage of a component or electronic element embedded on the carrier and/or accommodated in the vertical opening may be prevented.

According to a further embodiment, the method further comprises providing a functional coating layer on at least a part of a vertical side wall delimiting the vertical opening, wherein providing a functional coating layer comprises at least one of the group consisting of spray coating and inkjet printing. Hence, specific features of a functional coating layer may be efficiently and precisely achieved, such as a thickness of the functional coating layer of 25 μm or less.

According to an exemplary embodiment, the cavity stack section is not stepped (i.e., comprises essentially straight sidewalls), in particular wherein the central stack section defines the sidewall(s) of the cavity stack section.

In the following, further exemplary embodiments of the component carrier and/or the method will be explained.

In the context of the present document, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present document, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Scale Package (CSP)). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photo imageable or dry-etchable organic material like epoxy-based build-up material (such as epoxy-based build-up film) or polymer compounds (which may or may not include photo- and/or thermosensitive molecules) like polyimide or poly-benzoxazole.

In an embodiment, the at least one electrically insulating layer structure comprises at least one of the group consisting of a resin or a polymer, such as epoxy resin, cyanate ester resin, benzocyclobutene resin, bismaleimide-triazine resin, polyphenylene derivate (e.g. based on polyphenylenether, PPE), polyimide (PI), polyamide (PA), liquid crystal polymer (LCP), polytetrafluoroethylene (PTFE) and/or a combination thereof. Reinforcing structures such as webs, fibers, spheres, or other kinds of filler particles, for example made of glass (multilayer glass) in order to form a composite, could be used as well. A semi-cured resin in combination with a reinforcing agent, e.g., fibers impregnated with the above-mentioned resins is called prepreg. These prepregs are often named after their properties e.g., FR4 or FR5, which describe their flame retardant properties. Although prepreg particularly FR4 are usually preferred for rigid PCBs, other materials, in particular epoxy-based build-up materials (such as build-up films) or photoimageable dielectric materials, may be used as well. For high frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten, and magnesium. Although copper is usually preferred, other materials or coated versions thereof are possible as well, in particular materials coated with supra-conductive material or conductive polymers, such as graphene or poly(3,4-ethylenedioxythiophene) (PEDOT), respectively.

At least one component may be embedded in the component carrier and/or may be surface mounted on the component carrier. Such a component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SiC), gallium arsenide (GaAs), gallium nitride (GaN), gallium oxide (Ga₂O₃), indium gallium arsenide (InGaAs) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer, or a further component carrier, for example in a board-in-board configuration. The component may be surface mounted on the component carrier and/or may be embedded in an interior thereof. Moreover, also other components, in particular those which generate and emit electromagnetic radiation and/or are sensitive with regard to electromagnetic radiation propagating from an environment, may be used as component.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), gold (in particular hard gold), chemical tin, nickel-gold, nickel-palladium, etc.

It has to be noted that embodiments of the invention have been described with reference to different subject matters. In particular, some embodiments have been described with reference to method type claims whereas other embodiments have been described with reference to apparatus type claims. However, a person skilled in the art will gather from the above and the following description that, unless otherwise notified, in addition to any combination of features belonging to one type of subject matter also any combination between features relating to different subject matters, in particular between features of the method type claims and features of the apparatus type claims is considered as to be disclosed with this document.

The aspects defined above, and further aspects of the present invention are apparent from the examples of embodiment to be described hereinafter and are explained with reference to the examples of embodiment. The invention will be described in more detail hereinafter with reference to examples of embodiments, to which examples the invention is, however, not limited.

### BRIEF DESCRIPTION OF THE DRAWINGS

FIG. 1 shows a cross-sectional view of a stack of a component carrier comprising a central stack section, two cavity stack sections, and a vertical opening, according to an exemplary embodiment of the invention.

FIG. 2 shows an isometric view of a component carrier with a central stack section and two cavity stack sections, and a vertical opening, according to an exemplary embodiment of the invention.

FIG. 3 shows a cross-sectional view of an arrangement of a component carrier and an electronic element, according to an exemplary embodiment of the invention.

FIG. 4, FIG. 5 and FIG. 6 illustrate cross-sectional views of stacks obtained during carrying out a method of manufacturing a component carrier, according to exemplary embodiments of the invention.

FIG. 7 shows a cross-sectional view of a detail of the vertical opening of a component carrier, according to an exemplary embodiment of the invention.

### DETAILED DESCRIPTION OF ILLUSTRATED EMBODIMENTS

The illustrations in the drawings are schematically presented. It is noted that in different figures, similar or identical elements or features are provided with the same reference signs. In order to avoid unnecessary repetitions, elements, or features, which have already been elucidated with respect to a previously described embodiment, are not elucidated again at a later position of the description.

Furthermore, spatially relative terms, such as “front” and “back”, “above” and “below”, “left” and “right”, et cetera are used to describe an element's relationship to another element(s) as illustrated in the figures. Thus, the spatially relative terms may apply to orientations in use which may differ from the orientation depicted in the figures. Obviously, all such spatially relative terms refer to the orientation shown in the figures only for ease of description and are not necessarily limiting as a device according to an embodiment of the invention may assume orientations different than those illustrated in the figures when in use.

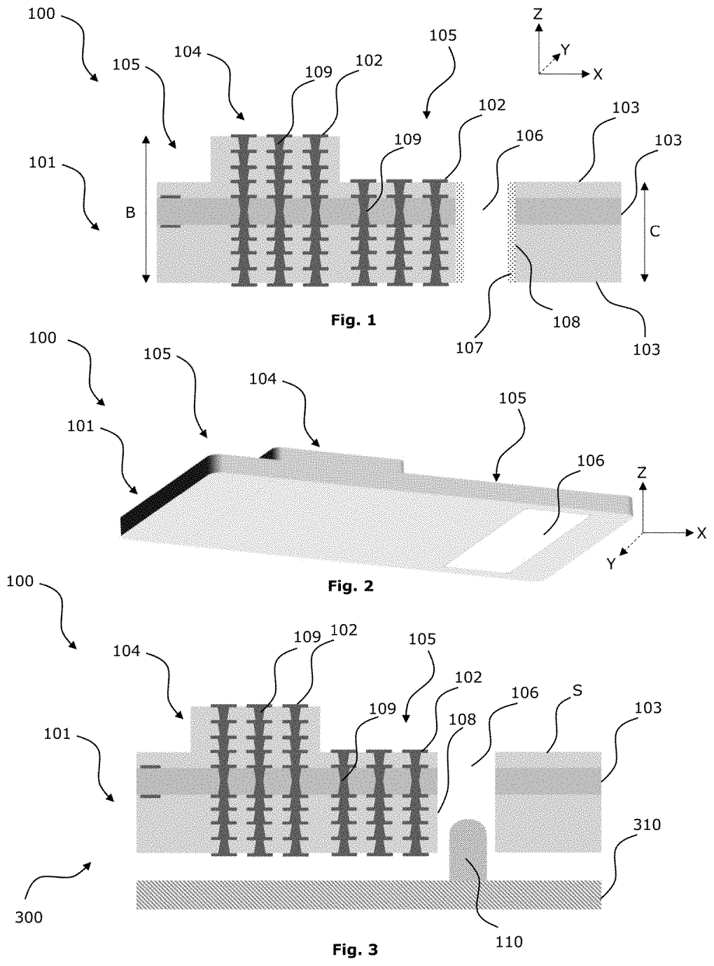

FIG. 1 shows a cross-sectional view of a stack 101 of a component carrier 100 comprising a central stack section 104, two cavity stack sections 105, and a vertical opening 106 (an opening area or opening cavity), according to an exemplary embodiment of the invention. The stack 101 comprises an electrically conductive layer structure 102 and electrically insulating layer structures 103, for example a core layer structure. The central stack section 104 is partially surrounded by the two cavity stack sections 105, or, in other words, the central stack section 104 is arranged between two cavity stack sections 105.

As can be taken from FIG. 1, the central stack section 104 is a protruding section with respect to the cavity stack sections 105 of the component carrier 100. Thus, the thickness B of the central stack section 104 is larger than the thickness C of the cavity stack section 105. Furthermore, a vertical opening 106 is formed in one of the cavity stack sections 105. The vertical opening 106 is depicted as being fully void. However, in other embodiments, the vertical opening 106 may also be partially void.

Reference sign 107 denotes a functional coating layer 107 covering at least one vertical side wall 108 delimiting the vertical opening 106. The functional coating layer 107 may for example be provided by means of spray coating or inkjet printing. As has been elucidated in detail above, the functional coating 107 may comprise at least one of a plurality of features, such as specific optical features and particularly a thickness of not more than 25 μm. The functional coating layer 107 may in particular be a black solder mask ink.

As can further be taken from FIG. 1, the electrically conductive layer structure 102 comprises a plurality of vertical through connections 109 extending through the central stack section 104, and the electrically conductive layer structure 102 also comprises a plurality of vertical through connections 109 extending through the cavity stack section 105. However, a part of the cavity stack section 105 comprising the vertical opening 106 is free of vertical through connections 109 in this example.

FIG. 2 shows an isometric view of a component carrier 100 with a central stack section 104 and two cavity stack sections 105, and a vertical opening 106, according to an exemplary embodiment of the invention. In this example, the vertical opening 106 comprises a rectangular shape and extends nearly over the whole width along the (y-axis) of the component carrier 100. It has to be noted, that the vertical opening is not limited to one specific shape or cross-sectional shape. In some embodiments, for example, the vertical opening may in particular be adapted to the shape of a camera, an optical sensor unit, a light detector etc., and as such, may have a (substantially) round shape, a (substantially) elliptical shape, a circular shape, a polygonal shape, etc.

FIG. 3 shows a cross-sectional view of an arrangement 300 of a component carrier 100 and an electronic element 110, according to an exemplary embodiment of the invention. The electronic element 110 is embedded on a further component carrier 310. Descriptively speaking, the electronic element 110 is not integrally formed with the component carrier 100, or, in other words, the electronic element 110 is physically separate (e.g., not embedded) from the component carrier 100. The vertical opening 106 of the component carrier 100 partially accommodates the electronic element 110, which may for example be an optical element such as a camera.

The electronic element 110 is protected by the vertical side walls 108 of the vertical opening 106 from damage, in particular from mechanical damage. In some embodiments, the electronic element 110 may extend all the way through the vertical opening 106 such that it protrudes from a first main surface S of the cavity stack section 105.

However, in the embodiment shown in FIG. 3, the electronic element 110 is fully protected by the vertical opening 106 because it only extends through part of the vertical opening 106. The vertical through connections 109 may for example serve to electrically connect the further component carrier 310 to the component carrier 100, and, in some embodiments, to yet another component carrier or component (both not shown), which may be connected on a side of the component carrier 100 opposing the side of the component carrier 100 at which the further component carrier 310 is arranged.

FIG. 3 also illustrates the use of a component carrier 100 to accommodate in the vertical opening 106 at least a part of an electronic element 110, which is not integrally formed with the component carrier 100 as described in detail above.

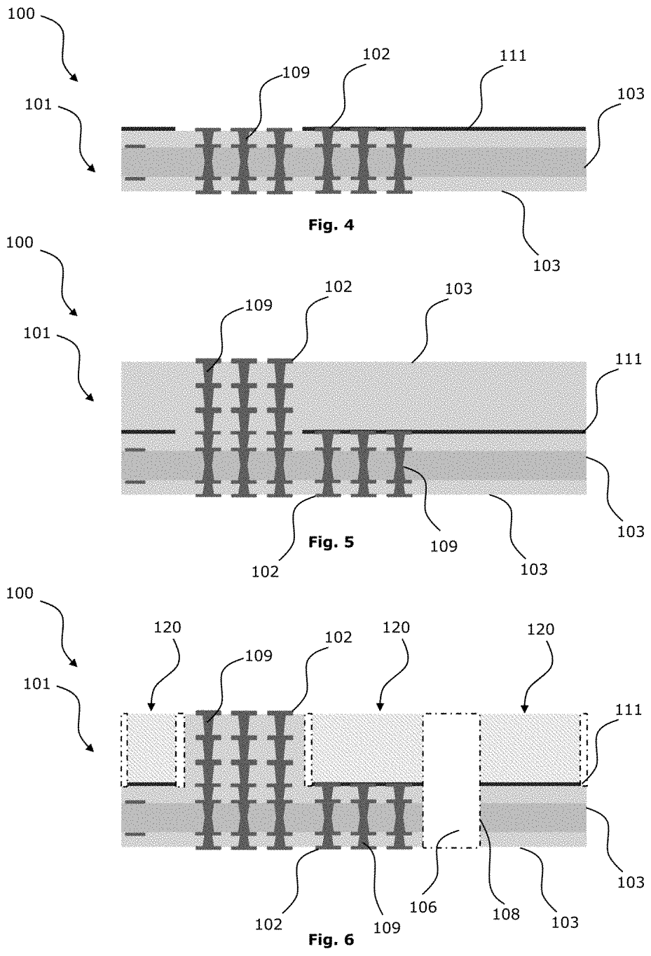

FIG. 4 to FIG. 6 illustrate cross-sectional views of stacks 101 obtained during carrying out a method of manufacturing a component carrier 100, according to exemplary embodiments of the invention.

In FIG. 4, a stack 101 comprising electrically insulating layer structures 103 and an electrically conductive layer structure 102 with vertical through connections 109 is shown. On a main surface of the stack 101, there is embedded a release layer 111.

Next, in FIG. 5, the stack 101 further comprises another electrically insulating layer structure 103 (and not-depicted electrically conductive layers), which is formed on the embedded release layer 111 (step of layer build-up). In the insulating layer structure 103 (and not-depicted electrically conductive layers), vertical through connections 109 of the electrically insulating layer structure 102 (and of the not-depicted electrically conductive layers) are formed, substantially electrically connecting both main surfaces of the stack 101.

In FIG. 6, cut-out portions 120 in the stack 101 are shown. The cut-out portions 120 are defined by cutting or drilling, in particular laser drilling. The drilling (symbolized by dotted lines) is performed down to the embedded release layer 111. Hence, the cut-out portions 120 are provided directly on the release layer 111. Removing the cut-out portion 120 from the stack 101 provides the cavity stack section, which at least partially surrounds the central stack section. Furthermore, in the so-formed cavity stack section 105, there is formed a vertical opening 106, for example by laser drilling or mechanical drilling. In other embodiments, the cavity stack section 105 may be formed by routing or cutting.

According to the embodiment shown in FIG. 6, forming the vertical opening 106 (symbolized by dotted lines) is carried out before forming the cavity stack section 105 of the stack 101. In other words, the vertical opening 106 is formed before the cut-out portions 120 are removed. Thus, a component carrier 100 as depicted for example in FIG. 1, and described in detail above, may be formed.

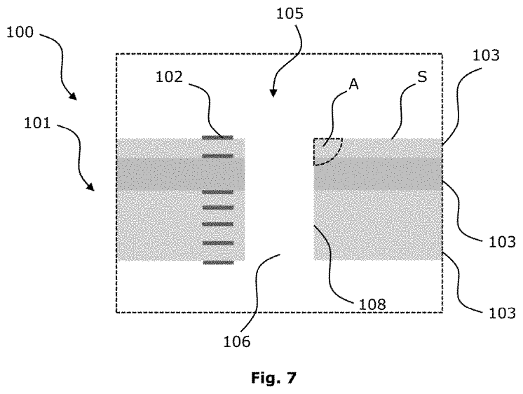

FIG. 7 shows a cross-sectional view of a detail of the stack 101 comprising the vertical opening 106, according to an exemplary embodiment of the invention. In the illustrated detail, the cavity stack section 105 comprises an electrically insulating layer structures 103 and the electrically insulating layer structure 102, which does, however, not have any vertical through connections 109.

An angle A between one vertical side wall 108 delimiting the vertical opening 106 and a first main surface S of the cavity stack section 105 is 90°. This can for example be achieved by forming the vertical opening 106 before forming the cavity stack section 105 of the stack 101 and furthermore by using one of cutting, laser drilling or mechanical drilling.

The angle A between the vertical side wall 108 and the main surface S being 90° (or at least in a range between 80° and 100°) can also be described as a clean, undamaged, sharp, and even edge or corner. This may be particularly advantageous for preventing light scattering and/or refraction, which could otherwise occur due to rough and damaged edges, surfaces, and corners (for example if the angle A were greater than 100°).

Furthermore, damage of a component or electronic element embedded on the component carrier 100 and/or accommodated in the vertical opening 106 may be prevented by providing the angle A in a range from 80° to 100°, in particular 90° as depicted in FIG. 7.

It should be noted that the term “comprising” does not exclude other elements or steps and the use of articles “a” or “an” does not exclude a plurality. Also, elements described in association with different embodiments may be combined.

Implementation of the invention is not limited to the preferred embodiments shown in the figures and described above. Instead, a multiplicity of variants is possible which variants use the solutions shown and the principle according to the invention even in the case of fundamentally different embodiments.

### LIST OF REFERENCE SIGNS

A Angle
B Thickness of a central stack section
C Thickness of a cavity stack section
S First main surface
100 Component carrier
101 Stack
102 Electrically conductive layer structure
103 Electrically insulating layer structure
104 Central stack section
105 Cavity stack section
106 Vertical opening
107 Functional coating layer
108 Vertical side wall
109 Vertical through connection
110 Electronic element
111 Release layer
120 Cut out portion
300 Arrangement
310 Further component carrier

1. A component carrier comprising a stack with at least one electrically conductive layer structure and at least one electrically insulating layer structure, the stack of the component carrier, comprising:
at least one central stack section;
at least one cavity stack section; and
at least one vertical opening formed in the cavity stack section;
wherein the cavity stack section at least partially surrounds the central stack section; and
wherein the thickness of the central stack section is larger than the thickness of the cavity stack section.

2. The component carrier according to claim 1, wherein the central stack section is arranged between at least two cavity stack sections.

3. The component carrier according to claim 1,
wherein the at least one vertical opening is at least partially void.

4. The component carrier according to claim 1, wherein the component carrier further comprises:
a functional coating layer covering at least one vertical side wall delimiting the vertical opening.

5. The component carrier according to claim 4, wherein the functional coating layer comprises at least one of the following features:
wherein the functional coating layer comprises a black coating;
wherein the functional coating layer has a thickness of 25 μm or less;
wherein the functional coating layer is configured to prevent light scattering or wherein the functional coating layer is configured to enhance light scattering;
wherein the functional coating layer is optically opaque or transparent;
wherein the functional coating layer is electrically insulating or electrically conductive;
wherein the functional coating layer is magnetic or non-magnetic;
wherein the protective coating layer is anticorrosive.

6. The component carrier according to claim 1, further comprising at least one of the following features:
wherein the at least one electrically conductive layer structure comprises a plurality of vertical through connections extending through the central stack section;
wherein the at least one electrically conductive layer structure comprises a plurality of vertical through connections extending through the cavity stack section,
wherein a component is embedded in or on the component carrier.

7. The component carrier according to claim 1, wherein the cavity stack section is free of vertical through connections.

8. The component carrier according to claim 1, wherein an angle between one vertical side wall delimiting the vertical opening and a first main surface of the cavity stack section is in the range between 80° and 100°.

9. The component carrier according to claim 1, wherein the component carrier is configured as one of the group which consists of a printed circuit board (PCB) and a substrate.

10. An arrangement, comprising:
a component carrier including a stack;
wherein the stack of the component carrier has at least one central stack section, at least one cavity stack section, and at least one vertical opening formed in the cavity stack section;
wherein the cavity stack section at least partially surrounds the central stack section; and
wherein the thickness of the central stack section is larger than the thickness of the cavity stack section; and
an electronic element, wherein at least a part of the electronic element extends through at least part of the at least one vertical opening.

11. The arrangement according to claim 10,
wherein the electronic element is not integrally formed with the component carrier.

12. The arrangement according to claim 10,
wherein the electronic element is physically separate from the component carrier.

13. The arrangement according to claim 10, wherein the electronic element is an optical element.

14. A method of manufacturing a component carrier, the method comprising:
providing a stack with at least one electrically conductive layer structure and at least one electrically insulating layer structure, wherein providing the stack comprises:
forming at least one central stack section in the stack;
forming at least one cavity stack section in the stack,
wherein the cavity stack section at least partially surrounds the central stack section,
wherein the thickness of the central stack section is larger than the thickness of the cavity stack section; and
forming at least one vertical opening in the cavity stack section.

15. The method according to claim 14,
wherein the forming the at least one vertical opening is accomplished by at least one of the group consisting of laser drilling and mechanical drilling.

16. The method according to claim 14, wherein providing the stack further comprises:
embedding a release layer in the stack,
defining, by cutting or drilling, a cut-out portion in the stack, wherein drilling is performed down to the embedded release layer to provide the cut-out portion directly on the release layer, and
removing the cut-out portion from the stack to provide the cavity stack section at least partially surrounding the central stack section.

17. The method according to claim 14, wherein forming the at least one cavity stack section of the stack is accomplished by routing.

18. The method according to claim 14, wherein forming the at least one vertical opening is carried out before forming the cavity stack section of the stack.

19. The method according to claim 14, further comprising:
providing a functional coating layer on at least a part of a vertical side wall delimiting the at least one vertical opening,
wherein providing a functional coating layer comprises at least one of the group consisting of spray coating and inkjet printing.

20. A method, comprising:
using a component carrier having a stack with at least one electrically conductive layer structure and at least one electrically insulating layer structure, the stack of the component carrier, comprising:
at least one central stack section;
at least one cavity stack section; and
at least one vertical opening formed in the cavity stack section;
wherein the cavity stack section at least partially surrounds the central stack section; and
wherein the thickness of the central stack section is larger than the thickness of the cavity stack section; and
accommodating in the at least one vertical opening at least a part of an electronic element which is not integrally formed with the component carrier.
